(19) United States
(12) Patent Application Publication
(10) Pub. No.: US 2013/0125955 A1
(43) Pub. Date: May 23, 2013

(54) SOLAR CELL MODULE, AND SOLAR PHOTOVOLTAIC DEVICE WITH SAME

(71) Applicant: Tsuyoshi Maeda, Osaka-shi (JP)

(72) Inventor: Tsuyoshi Maeda, Osaka-shi (JP)

(73) Assignee: SHARP KABUSHIKI KAISHA, Osaka-shi, Osaka (JP)

(21) Appl. No.: 13/700,863

(22) PCT Filed: Apr. 14, 2011
(86) PCT No.: PCT/JP2011/059290

§ 371 Date: Nov. 29, 2012

(30) Foreign Application Priority Data
Jun. 2, 2010 (JP) 2010126792

(51) Int. Cl. H01L 31/052; H01L 31/0232

(52) U.S. Cl. CPC H01L 31/0525; H01L 31/02327
USPC 136/246; 136/259

(57) ABSTRACT

A solar cell module (1) includes a solar cell (2), a fluorescent light collecting plate (3), and reflection plates (4). The fluorescent light collecting plate (3) faces a light receiving surface through which external light (6) such as sunlight or illumination light enters the fluorescent light collecting plate (3). The solar cell (2) is provided to at least one of the end surfaces (intersecting surfaces each intersecting the light receiving surface) of the fluorescent light collecting plate (3). To the other end surfaces of the fluorescent light collecting plate (3), the reflection plates (4) are provided. The end surfaces of the fluorescent light collecting plate (3), to which end surfaces no solar cell (2) is provided, are arranged so as not to be parallel to each other. Therefore, light guided to any of the end surfaces to which no the solar cell (2) is provided is reflected by the reflection plate (4) on that end surface, and finally reaches the solar cell (2) where the light is used for power generation.

### TECHNICAL FIELD

The present invention relates to a solar cell module and a solar photovoltaic device with same.

### BACKGROUND ART

A solar cell has been recognized as an important clean energy source, and is thus in increasing demand. The solar cell is used in various fields ranging from a power energy source for large equipment to a small power source for a precision electronic device. Various solar photovoltaic devices including solar cells are coming into wide use.

FIG. 6 illustrates a usage example of a conventional solar photovoltaic device. As illustrated in FIG. 6, a general solar photovoltaic device 20 which is in current use is used with solar cell panels 21 laid all over a surface to face the sun. This is for efficient use of solar energy. Such solar cell panels 21 are usually constituted by opaque semiconductors and therefore cannot be placed on top of each other. Therefore, in order to collect sufficient sunlight 26, it is necessary to use large-area solar cell panels 21. This necessitates a large installation area for the solar photovoltaic device 20.

Under such circumstances, Patent Literature 1 discloses a special way of reducing the area of a solar photovoltaic device. Specifically, Patent Literature 1 discloses a solar photovoltaic device which includes a solar cell attached to a side surface that is perpendicular to a light receiving surface of a transparent light absorbing/emitting plate in which fluorescent materials are dispersed. Further, reflective layers are provided on side surfaces of the solar photovoltaic device, which side surfaces are other than the side surface to which the solar cell is attached. According to this configuration, by use of the light absorbing/emitting plate as a window surface of a building, sunlight that has entered the light absorbing/emitting plate through the light receiving surface is guided through the light absorbing/emitting plate and collected on the solar cell. This makes it possible to achieve efficient use of solar energy with a small-area solar photovoltaic device.

### CITATION LIST

### Patent Literature

Patent Literature 1

Japanese Patent Application Publication, Jitsukaisho, No. 61-136559 A (Publication Date: Aug. 25, 1986)

### SUMMARY OF INVENTION

### Technical Problem

According to the configuration in which a solar cell is provided to an edge of a transparent fluorescent screen (e.g., the configuration of the solar photovoltaic device disclosed in Patent Literature 1), a solar photovoltaic device can be reduced in its area. However, the solar photovoltaic device uses sunlight not efficiently. The reason therefor is explained with reference to FIG. 7. FIG. 7 is a view schematically showing a solar photovoltaic device 30 disclosed in Patent Literature 1, as seen from a light receiving surface side.

Light 36 that is guided in a direction perpendicular to an end surface to which no solar cell 32 is provided, which light 36 is part of light that has entered the solar photovoltaic device 30 through the light receiving surface, is merely reflected repeatedly between the end surface and its opposite end surface by a reflection plate 34, and thus is not collected on the solar cell 32 (see FIG. 7). As a result, since the light that has been guided in a direction perpendicular to the end surface to which no solar cell 32 is provided does not reach the solar cell 32, the solar photovoltaic device 30 is low in light use efficiency.

The present invention has been made in view of the above problems, and an object of the present invention is to provide a solar cell module and a solar photovoltaic device including the solar cell module, each of which is capable of generating electric power with high efficiency by efficiently collecting external light onto a solar cell.

### Solution to Problem

In order to attain the above object, a solar cell module in accordance with the present invention includes: a light collecting plate which (i) has a light receiving surface and a plurality of intersecting surfaces each of which intersects the light receiving surface and (ii) contains a fluorescent material; and a solar cell which is provided to at least one of the plurality of intersecting surfaces, a reflection plate being provided to intersecting surfaces other than the at least one of the plurality of intersecting surfaces to which the solar cell is provided, and the intersecting surfaces to which the reflection plate is provided extending in respective directions that intersect each other.

According to the above configuration, the end surfaces (the intersecting surfaces each of which intersects the light receiving surface) of the light collecting plate, which end surfaces are other than the end surface to which the solar cell is provided, are arranged so as not to be parallel to each other. According to this configuration, light that is guided to any of the end surfaces to which no solar cell is provided is reflected by the reflection plate provided on that end surface, and finally reaches the solar cell where the light is used for power generation.

Assume that the end surfaces to which no solar cell is provided are arranged parallel to each other. If this is the case, part of light that has entered the light collecting plate, which part has been guided in a direction perpendicular to either of the two end surfaces which are parallel to each other, is merely reflected repeatedly between the two end surfaces which are parallel to each other, and thus cannot enter the solar cell. In this regard, the light collecting plate in accordance with the present invention is arranged such that end surfaces of the light collecting plate, to which end surfaces no solar cell is provided, are arranged so as not to be parallel to each other. Therefore, light is not repeatedly reflected between the two end surfaces. This makes it possible to collect most of the external light which has entered the solar cell module on the solar cell, and thus possible to increase electric power generation efficiency of the solar cell module.

Moreover, since the solar cell is provided to an end surface of the light collecting plate, it is possible to achieve sufficient power generation efficiency despite the small area of the solar cell. Further, since the solar cell module can be designed with a high degree of freedom, it is possible to realize a highly-efficient solar photovoltaic system by using the solar cell module attached to a window frame of a building, a window frame of a car, or a roof.

Further, in order to attain the above object, a solar photovoltaic device in accordance with the present invention includes a plurality of solar cell modules each of which is set forth in any one of above descriptions, each of the light collecting plates being a trapezoid, and the plurality of solar cell modules being arranged such that an upper base of one light collecting plate is adjacent to a lower base of another light collecting plate that is adjacent to the one light collecting plate. According to the above configuration, it is possible to provide a solar photovoltaic device that is capable of efficiently converting solar energy to electric power with use of small-area solar cells.

Additional objects, features, and strengths of the present invention will be made clear by the description below. Further, the advantages of the present invention will be evident from the following explanation in reference to the drawings.

### Advantageous Effects of Invention

According to the present invention, it is possible to collect most of external light that has entered a solar cell module onto a solar cell. This makes it possible to increase power generating efficiency of the solar cell module. Furthermore, since the solar cell is provided to an end surface of a light collecting plate, it is possible to achieve sufficient power generation efficiency despite the small area of the solar cell. Further, since the solar cell module can be designed with a high degree of freedom, it is possible to realize a highly-efficient solar photovoltaic system by attaching the solar cell module to a window frame of building, a window frame of a car, or a roof.

### BRIEF DESCRIPTION OF DRAWINGS

FIG. 1

FIG. 1 is a view of a solar cell module in accordance with an embodiment of the present invention, as seen from a light receiving surface side.

FIG. 2

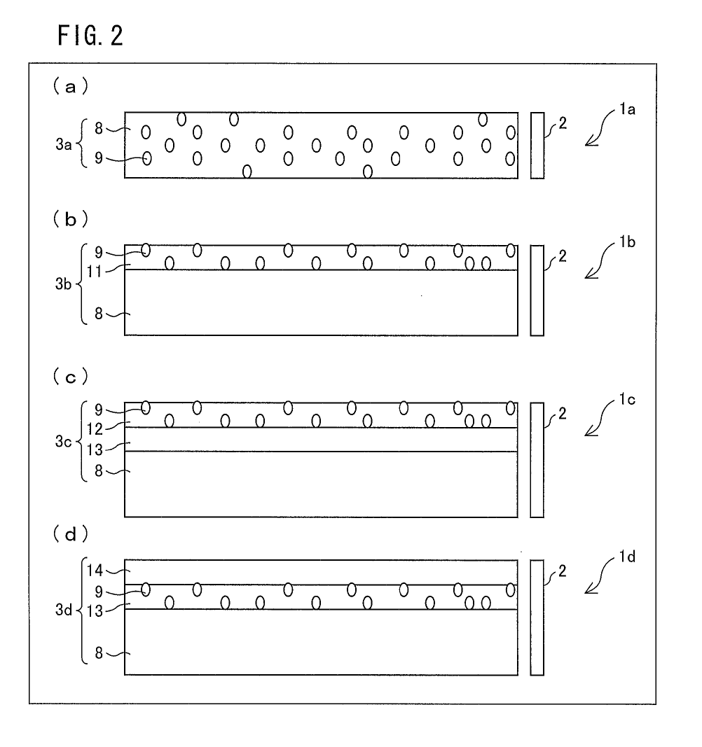

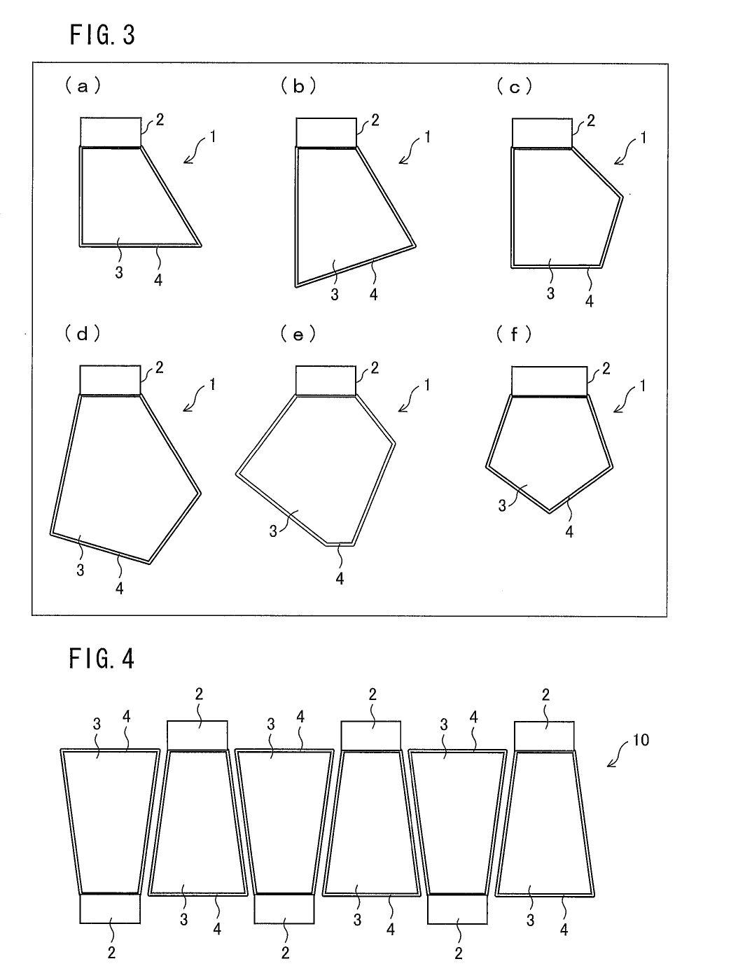

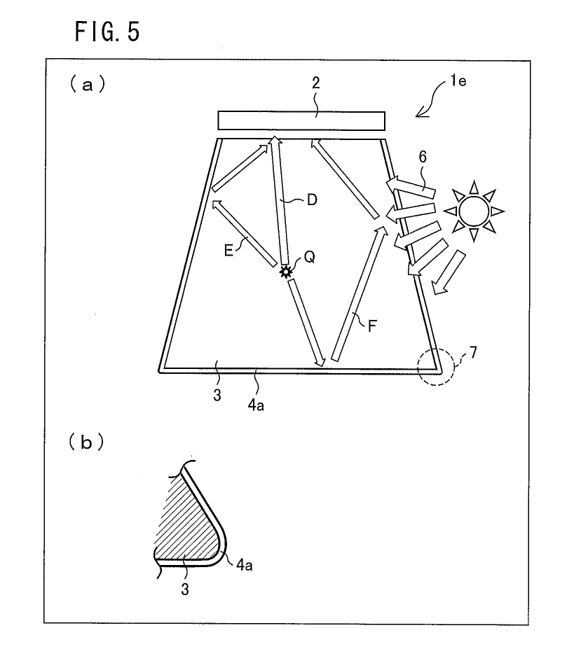

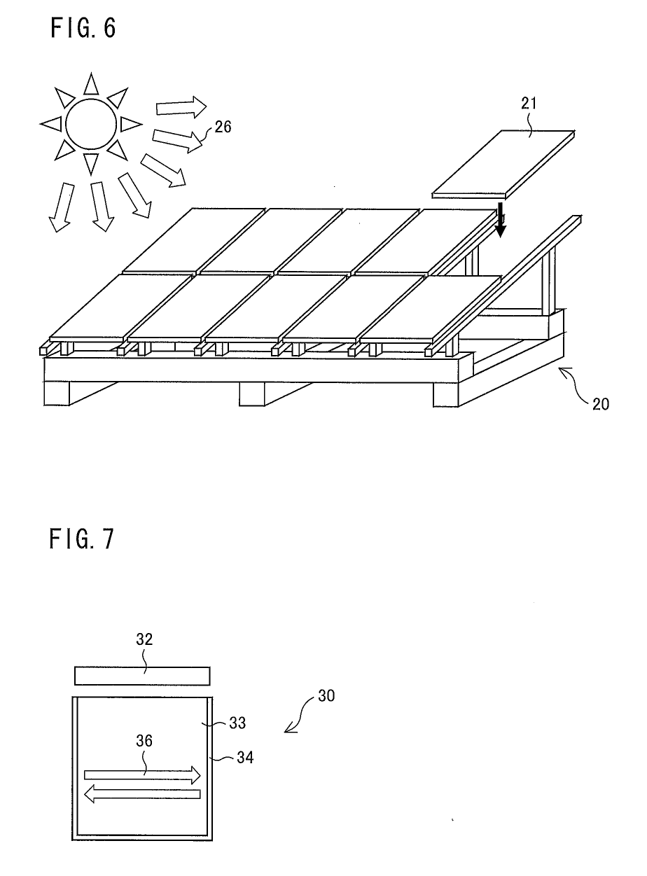

(a) of FIG. 2 is a view schematically illustrating a cross section of a fluorescent light collecting plate in accordance with the embodiment of the present invention. (b) of FIG. 2 is a view schematically illustrating a cross section of another fluorescent light collecting plate in accordance with the embodiment of the present invention. (c) of FIG. 2 is a view schematically illustrating a cross section of a further fluorescent light collecting plate in accordance with the embodiment of the present invention. (d) of FIG. 2 is a view schematically illustrating a cross section of still a further fluorescent light collecting plate in accordance with the embodiment of the present invention.

FIG. 3

(a) of FIG. 3 is a view of a solar cell module in accordance with the embodiment of the present invention, as seen from a light receiving surface side. (b) of FIG. 3 is a view of another solar cell module in accordance with the embodiment of the present invention, as seen from the light receiving surface side. (c) of FIG. 3 is a view of a further solar cell module in accordance with the embodiment of the present invention, as seen from the light receiving surface side. (d) of FIG. 3 is a view of still a further solar cell module in accordance with the embodiment of the present invention, as seen from the light receiving surface side. (e) of FIG. 3 is a view of still yet another solar cell module in accordance with the embodiment of the present invention, as seen from the light receiving surface side. (f) of FIG. 3 is a view of still yet a further solar cell module in accordance with the embodiment of the present invention, as seen from the light receiving surface side.

FIG. 4

FIG. 4 is a view of solar cell modules in accordance with the embodiment of the present invention, as seen from the light receiving surface side.

FIG. 5

(a) of FIG. 5 is a view of a solar cell module in accordance with another embodiment of the present invention, as seen from a light receiving surface side. (b) of FIG. 5 is an enlarged view of a corner of the solar cell module in accordance with the another embodiment of the present invention.

FIG. 6

FIG. 6 is a view illustrating a usage example of a conventional solar photovoltaic device.

FIG. 7

FIG. 7 is a view of a conventional solar photovoltaic device as seen from a light receiving surface side.

### DESCRIPTION OF EMBODIMENTS

The following description discusses an embodiment of the present invention in details with reference to the drawings.

### First Embodiment

(Configuration of Solar Cell Module 1)

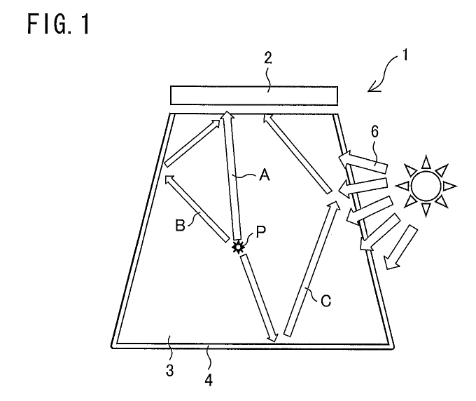

First, a first embodiment of a solar cell module 1 in accordance with the present invention is described with reference to FIG. 1. FIG. 1 is a view of the solar cell module 1 as seen from a light receiving surface side.

As illustrated in FIG. 1, the solar cell module 1 includes a solar cell 2, a fluorescent light collecting plate 3 (a light collecting plate), and reflection plates 4. The fluorescent light collecting plate 3 is in the form of a plate, and has (i) a light receiving surface through which external light 6 such as sunlight or illumination light enters the fluorescent light collecting plate 3 and (ii) intersecting surfaces (i.e., end surfaces, or side surfaces) each of which intersects the light receiving surface. The solar cell 2 is provided to at least one of the end surfaces (intersecting surfaces each of which intersects the light receiving surface) of the fluorescent light collecting plate 3, and the reflection plates 4 are provided to the other end surfaces of the fluorescent light collecting plate 3. FIG. 1 illustrates a configuration in which the solar cell 2 is provided to one of the end surfaces of the fluorescent light collecting plate 3, and the reflection plates 4 are provided to the other three end surfaces.

The external light 6 which has entered the fluorescent light collecting plate 3 through the light receiving surface of the solar cell module 1 is guided through the fluorescent light collecting plate 3, and finally collected on the solar cell 2. The light thus collected is used for power generation by the solar cell 2. Note here that the solar cell module 1 in accordance with the present embodiment is characterized in that end surfaces, of the fluorescent light collecting plate 3, which are other than the end surface to which the solar cell 2 is provided are arranged so as not to be parallel to each other. For example, in the case of FIG. 1, the three end surfaces to which no solar cell 2 is provided are not parallel to each other. According to this configuration, most of the external light 6 which has entered the solar cell module 1 is collected on the solar cell 2. This makes it possible for the solar cell module 1 to efficiently generate electric power.

This configuration is described below with a specific example. For example, part of external light 6 incident on a point P of the fluorescent light collecting plate 3, which part has been guided in a direction of the arrow A in FIG. 1, directly enters the solar cell 2. On the other hand, parts of the external light 6, which parts have been guided in respective directions of the arrows B and C, are each reflected by the reflection plate 4, and finally enter the solar cell 2. Assume that the end surfaces to which no solar cell 2 is provided are arranged parallel to each other. If this is the case, part of light that has entered the fluorescent light collecting plate 3, which part has been guided in a direction perpendicular to either of the two end surfaces which are parallel to each other, is merely reflected repeatedly between the two end surfaces which are parallel to each other and thus cannot enter the solar cell 2. In this regard, the fluorescent light collecting plate 3 in accordance with the present embodiment is arranged such that the end surfaces other than the end surface to which the solar cell 2 is provided are arranged so as not to be parallel to each other. Therefore, light is not repeatedly reflected between the two end surfaces. This makes it possible to collect most of the external light 6 which has entered the solar cell module 1 on the solar cell 2, and thus possible to increase electric power generation efficiency of the solar cell module 1.

Note that the present invention has been made to prevent light from being repeatedly reflected between two end surfaces of the fluorescent light collecting plate 3, to which end surfaces no solar cell 2 is provided. It is needless to say that the present embodiment is applicable to a case where the fluorescent light collecting plate 3 has a plurality of end surfaces on which no solar cell 2 is provided.

(Each Member of Solar Cell Module 1)

The following description discusses a specific configuration of the solar cell module 1.

The fluorescent light collecting plate 3 is one that converts the wavelength of light that has entered the fluorescent light collecting plate 3 to a wavelength falling within a range effective for photoelectric conversion by the solar cell 2. The fluorescent light collecting plate 3 is not limited, provided that it guides light that has entered it through the light receiving surface and collects the light on the solar cell 2 provided to an end surface. Such a fluorescent light collecting plate 3 is for example a plate obtained by mixing a fluorescent material into a light guide plate, a plate obtained by applying a fluorescent material to a light guide plate, or the like. Specifically, the fluorescent material can be a well-known fluorescent material. Examples of the well-known fluorescent material include: hydrochlorides of rare earth metals and sulfates of rare earth metals such as coumarin fluorochrome, samarium, terbium, europium, gadolinium and dysprosium; transition metalates such as calcium molybdate and calcium tungstate; aromatic hydrocarbons such as benzene and naphthalene; and phthalein dyes such as eosin and fluorescein. Note, however, that the fluorescent material is not limited to those listed above. Further, the light guide plate can be a well-known light guide plate. Examples of the well-known light guide plate include an acrylic substrate, a glass substrate and a polycarbonate substrate. Note, however, that the light guide plate is not limited those listed above.

The content of the fluorescent material in the fluorescent light collecting plate 3 is not particularly limited. Note, however, that it is preferable that the content of the fluorescent material is 10 wt % or less. Provided that the content is 10 wt % or less, it is possible to reduce multiple scattering by the fluorescent material and thus possible to realize efficient fluorescence emission.

The thickness of the fluorescent light collecting plate 3 is not particularly limited. Note, however, that the thickness is preferably 1 mm to 10 mm, and is further preferably 2 mm to 5 mm. Provided that the thickness falls within the above range, it is possible to obtain the fluorescent light collecting plate 3 which is light-weight and strong. The length of each side of the fluorescent light collecting plate 3 is not particularly limited. The area of the light receiving surface of the fluorescent light collecting plate 3 is not particularly limited.

In a case where the solar cell module 1 is to be attached to a window frame of a building, the fluorescent light collecting plate 3 is constituted by an acrylic substrate or the like which can be attached to a window frame and which is large and thin enough to function as a window surface. Further, in a case where the solar cell module 1 is to be provided on a roof, the size and the thickness of the fluorescent light collecting plate 3 can be arranged as appropriate depending on the conditions such as installation area.

The fluorescent light collecting plate 3 can be produced by for example any of the following four methods. The methods are described with reference to FIG. 2. (a) to (d) of FIG. 2 are views schematically illustrating cross sections of respective fluorescent light collecting plates 3a to 3d. In (a) to (d) of FIG. 2, the reflection plates 4 are omitted for clear illustration of the fluorescent light collecting plates 3a to 3d.

First, the following describes a fluorescent material dispersion method. According to this method, the fluorescent light collecting plate 3a is formed by dispersing a fluorescent material 9 in a light guide plate 8 (see (a) of FIG. 2). A solar cell 2 is provided to at least one of the end surfaces of the fluorescent light collecting plate 3a, and reflection plates 4 are bonded to the other end surfaces. This completes a solar cell module 1a.

Next, the following describes a fluorescent material coating method. According to this method, the fluorescent light collecting plate 3b is formed by applying a coating agent 11 to a surface of the light guide plate 8, in which coating agent 11 the fluorescent material 9 is dispersed (see (b) of FIG. 2). A light source 2 is provided to at least one of the end surfaces of the fluorescent light collecting plate 3b, and reflection plates 4 are bonded to the other end surfaces. This completes a solar cell module 1b.

Next, the following describes a fluorescent sheet attachment method. According to this method, the fluorescent light collecting plate 3c is formed by bonding a sheet 12 to the light guide plate 8 via an adhesive 13, in which sheet 12 the fluorescent material 9 is dispersed (see (c) of FIG. 2). A solar cell 2 is provided to at least one of the end surfaces of the fluorescent light collecting plate 3c, and reflection plates 4 are bonded to the other end surfaces. This completes a solar cell module 1c.

Next, the following describes a fluorescent adhesive attachment method. According to this method, the fluorescent light collecting plate 3d is formed by (i) dispersing the fluorescent material 9 in the adhesive 13 and (ii) bonding a transparent sheet 14 to the light guide plate 8 via the adhesive 13 (see (d) of FIG. 2). A solar cell 2 is provided to at least one of the end surfaces of the fluorescent light collecting plate 3d, and reflection plates 4 are bonded to the other end surfaces. This completes a solar cell module 1d.

The fluorescent light collecting plate 3 in accordance with the present embodiment can be produced by any of the foregoing production methods. Note, however, that this does not imply any limitation.

The reflection plate 4 can be a known reflection plate such as an aluminum reflection plate, a silver (Ag) reflection plate, a dielectric laminate film or the like. Note, however, that the reflection plate 4 is not limited to those listed above. The size of the reflection plate 4 is not particularly limited, but it is preferable that the width of the surface which is to be bonded to the fluorescent light collecting plate 3 is the same as the thickness of the fluorescent light collecting plate 3. This makes it possible to efficiently reflect light that is guided through the fluorescent light collecting plate 3 and reaches the end surfaces to which the reflection plates 4 are provided.

The solar cell 2 can be a known solar cell such as an amorphous silicon (a-Si) solar cell, a polycrystalline silicon solar cell, a single-crystal silicon solar cell, a compound solar cell or the like. Note, however, that the solar cell 2 is not limited to those listed above. The solar cell 2 is attached to an end surface (side surface that intersects the light receiving surface) of the fluorescent light collecting plate 3 with a well-known light-transmitting adhesive or the like. Note here that the solar cell 2 is provided to at least one of the end surfaces of the fluorescent light collecting plate 3. It is preferable that the solar cell 2 is provided to at least an end surface that is the shortest in length. This makes it possible to minimize the necessary area of the solar cell 2, and further possible to provide a solar cell module 1 that generates electric power with high efficiency despite the small area of the solar cell 2.

The size of the solar cell 2 is not particularly limited, but it is preferable that the width of a light receiving part of the solar cell 2 is the same as the thickness of the fluorescent light collecting plate 3. This makes it possible for the solar cell 2 to efficiently receive light that has been guided through the fluorescent light collecting plate 3 and reached the end surface to which the solar cell 2 is provided. Such a solar cell module 1 as that illustrated in

FIG. 1 was prepared, and its power generation efficiency was examined. First, a trapezoidal fluorescent light collecting plate 3 (thickness: 10 mm, the area of a light receiving surface: 1 m²) was prepared by dispersing, in acrylic resin, approximately 3 wt % of coumarin fluorochrome which emits light upon irradiation with sunlight. To one of the end surfaces of the fluorescent light collecting plate 3 thus prepared, a solar cell 2 whose light receiving part was 10 mm wide was provided. To the other end surfaces, aluminum reflection plates which serve as reflection plates 4 were bonded with an acrylic adhesive. The power generated when the solar cell module 1 thus prepared was placed outside in clear weather was approximately 23 W.

For comparison, a 1-m-square fluorescent light collecting acrylic plate (thickness: 10 mm) was prepared from the same material as the foregoing solar cell module 1. To one of the end surfaces of the fluorescent light collecting acrylic plate thus prepared, a solar cell 2 whose light receiving part was 10 mm wide was provided. To the other end surfaces, an aluminum reflection plate is bonded with an acrylic adhesive. The power generated when the solar cell module thus prepared was placed outside in clear weather was approximately 20 W.

As described above, the solar cell module 1 in accordance with the present embodiment generates power more efficiently than a conventional solar cell module. This is because the solar cell module 1 collects a higher percentage of light than a conventional solar cell module. Specifically, when the solar cell module 1 is irradiated with sunlight, a fluorescent material in the acrylic resin (i) absorbs part of the sunlight, which part is light of a specific wavelength region and (ii) emits light of yellow-green wavelength. Approximately 75% of the light of yellow-green wavelength is guided through the fluorescent light collecting plate 3. Light that is guided directly to the end surface to which the solar cell 2 is provided is used for power generation by the solar cell 2. On the other hand, light that is guided to any of the three end surfaces to which no solar cell 2 is provided is reflected by the reflection plates 4 provided to that end surface, and finally reaches the solar cell 2 where the light is used for power generation by the solar cell 2. As a result, most of the light which has been guided through the fluorescent light collecting plate 3 finally reaches the solar cell 2. As such, the solar cell module 1 collects light with high efficiency.

Furthermore, since the solar cell 2 is provided on an end surface of the fluorescent light collecting plate 3, the solar cell module 1 achieves sufficient power generation efficiency despite the small area of the solar cell 2. Further, the solar cell module 1 can be designed with a high degree of freedom. This makes it possible to realize a highly efficient solar photovoltaic system by attaching the solar cell module 1 to a window frame of a building or a window frame of a car or by attaching the solar cell module 1 to a roof.

(Example of Shape of Fluorescent Light Collecting Plate 3)

FIG. 1 illustrates a trapezoid fluorescent light collecting plate 3. Note, however, that the shape of the fluorescent light collecting plate 3 is not limited to a trapezoid, and therefore can be other shape. FIG. 3 illustrates examples of the shape of the fluorescent light collecting plate 3. (a) to (f) of FIG. 3 are views each showing a solar cell module 1 as seen from a light receiving surface side.

As illustrated in (a) to (f) of FIG. 3, the shape of the fluorescent light collecting plate 3 is not particularly limited provided that (i) the fluorescent light collecting plate 3 has at least one end surface to which the solar cell 2 is provided and (ii) the end surfaces other than the end surface to which the solar cell 2 is provided are arranged so as not to be parallel to each other. Therefore, the fluorescent light collecting plate 3 is not limited to a quadrangle, and therefore can be other polygon such as a pentagon or a hexagon (see (c) to (f) of FIG. 3). Regardless of the shape of the fluorescent light collecting plate 3, the fluorescent light collecting plate 3 is capable of efficiently guiding incident light to the solar cell 2 provided that the end surfaces on which no solar cell 2 is provided are arranged so as not to be parallel to each other. That is, it is only necessary that a plurality of end surfaces to which the reflection plates 4 are provided be arranged so as to extend to intersect one another.

(Solar Photovoltaic Device)

FIG. 4 illustrates a solar photovoltaic device including a solar cell module 1, which is an example of a solar photovoltaic device using a solar cell module 1 in accordance with the present embodiment. FIG. 4 is a view of a solar photovoltaic device 10 which includes solar cell modules 1, as seen from the light receiving surface side.

As illustrated in FIG. 4, the solar photovoltaic device 10 includes a plurality of solar cell modules 1. In FIG. 4, each of the solar cell modules 1 is a trapezoid. Therefore, it is possible to efficiently arrange the plurality of solar cell modules 1 in a certain area, by arranging the plurality of solar cell modules 1 such that an upper base of a fluorescent light collecting plate 3 of one solar cell module 1 is adjacent to a lower base of a fluorescent light collecting plate 3 of another solar cell module 1. It is only necessary to appropriately choose solar cell modules 1 which are capable of being arranged efficiently in a place where the solar photovoltaic device 10 is desired to be provided.

The solar photovoltaic device 10 can include for example a storage battery for storing therein output from the solar cell modules 1. Further, the solar photovoltaic device 10 can be attached to for example a window or a roof of a building or to a window of a car, and thus is capable of efficiently converting solar energy into electric power with use of small-area solar cells 2.

### Second Embodiment

The following description discusses a solar cell module in accordance with a second embodiment of the present invention with reference to FIG. 5. (a) of FIG. 5 is a view of a solar cell module 1e as seen from a light receiving surface side. (b) of FIG. 5 is an enlarged view of a part 7 illustrated in (a) of FIG. 5.

According to the earlier-described first embodiment, the reflection plates 4 are bonded to the end surfaces to which no solar cell 2 is provided. The end surfaces to which the reflection plates 4 are bonded are arranged at an angle to each other. That is, a portion (a corner of the solar cell module 1) where the end surfaces to which the reflection plates 4 are bonded intersect each other has an angular shape. In this case, part of light that has entered the solar cell module 1, which part has been guided to the corner of the solar cell module 1, may be absorbed by the corner. As a result, the solar cell module 1 decreases in light use efficiency.

In view of this, according to the solar cell module 1e in accordance with the present embodiment, a portion (a corner of the solar cell module 1e) where the end surfaces to which reflection plates 4a are bonded intersect each other has a curved surface (see (b) of FIG. 5). That is, the corner of the solar cell module 1e is rounded. This is achieved by arranging end surfaces of the fluorescent light collecting plate 3, to which end surfaces the reflection plates 4a are bonded, such that a portion where the end surfaces intersect each other has a curved surface. Further, a strip of continuous reflection plate 4a is bonded to the end surfaces of the fluorescent light collecting plate 3, instead of reflection plates 4a bonded to the respective end surfaces of the fluorescent light collecting plate 3. Note here that the radius of curvature of a corner of the fluorescent light collecting plate 3 (the solar cell module 1e) is not particularly limited.

According to the above configuration, part of light that has entered the solar cell module 1e, which part has been guided to the corner of the solar cell module 1e, is reflected by the curved surface of the corner. Therefore, it is possible to prevent the light guided to the corner of the solar cell module 1e from being absorbed by the corner. As a result, the solar cell module 1e becomes capable of collecting more light and using light more efficiently.

Further, it is easier to bond the reflection plate 4a to end surfaces of the fluorescent light collecting plate 3, because a portion where the end surfaces intersect each other has a curved surface. This also prevents breaking or chipping of the solar cell module 1e during transportation of the solar cell module 1e, and thus improves the handleability of the solar cell module 1e.

The present embodiment is the same as the first embodiment except that the corner of the solar cell module 1e has a curved surface. That is, according also to the solar cell module 1e, end surfaces of the fluorescent light collecting plate 3, to which end surfaces no solar cell 2 is provided, are arranged so as not to be parallel to each other. According to the configuration, most of external light 6 that has entered the solar cell module 1e is collected on the solar cell 2, and thus the solar cell module 1e is capable of efficiently generating electric power. For example, part of external light 6 incident on a point Q of the fluorescent light collecting plate 3, which part has been guided in a direction of the arrow D shown in FIG. 5, directly enters the solar cell 2. On the other hand, parts of the external light 6, which parts have been guided in respective directions of the arrows E and F, are each reflected by the reflection plate 4a, and finally enter the solar cell 2. Since the fluorescent light collecting plate 3 in accordance with the present embodiment is arranged such that end surfaces other than the end surface to which the solar cell 2 is provided are arranged so as not to be parallel to each other like above, light is not repeatedly reflected between two end surfaces. This makes it possible to collect most of the external light 6 which has entered the solar cell module 1e on the solar cell 2, and thus possible to increase power generation efficiency of the solar cell module 1e. Note that, since the solar cell module 1e is the same as the first embodiment except that the corner of the solar cell module 1e has a curved surface, the other configurations of the solar cell module 1e are not described here.

The present invention is not limited to the description of the embodiments above, but may be altered within the scope of the claims. An embodiment based on a proper combination of technical means disclosed in different embodiments is encompassed in the technical scope of the present invention.

### Overview of Embodiments

As has been described, the solar cell module in accordance with the present invention is configured such that the at least one of the plurality of intersecting surfaces to which the solar cell is provided includes an intersecting surface whose portion intersecting the light receiving surface of the light collecting plate is the shortest in length of those of the plurality of intersecting surfaces.

According to the above configuration, it is possible to minimize the necessary area of the solar cell, and further possible to provide a solar cell module that is highly efficient in electric power generation despite the small area of the solar cell.

The solar cell module in accordance with the present invention is configured such that a portion, of the light collecting plate, in which adjacent ones of the plurality of intersecting surfaces intersect each other has a curved surface.

According to the above configuration, part of light that has entered the solar cell module, which part has been guided to the corner (a portion where the end surfaces to which the reflection plates are provided intersect each other) of the solar cell module, is reflected by the curved surface of the corner. Therefore, it is possible to prevent the light guided to the corner of the solar cell module from being absorbed by the corner. As a result, the solar cell module becomes capable of collecting more light and using light more efficiently.

Further, it is easier to bond the reflection plate to end surfaces of the light collecting plate, because a portion where the end surfaces intersect each other has a curved surface. This also prevents breaking or chipping of the solar cell module during transportation of the solar cell module, and thus improves the handleability of the solar cell module.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The present invention provides a solar cell module which can be designed with a high degree of freedom and which collects light with high efficiency. Therefore, the present invention is suitable for use in a solar photovoltaic system attached to a window of a building or of a car, a roof of a building, or the like.

### REFERENCE SIGNS LIST

1, 1a to 1e Solar cell module
2, 32 Solar cell
3, 3a to 3d, 33 Fluorescent light collecting plate
4, 4a, 34 Reflection plate
6 External Light
8 Light guide plate
9 Fluorescent material
10, 20, 30 Solar photovoltaic device
11 Coating agent
12 Sheet
13 Adhesive
21 Solar cell Panel
26 Sunlight
36 Light

1. A solar cell module comprising:
a light collecting plate which (i) has a light receiving surface and a plurality of intersecting surfaces each of which intersects the light receiving surface and (ii) contains a fluorescent material; and
a solar cell which is provided to at least one of the plurality of intersecting surfaces,
a reflection plate being provided to intersecting surfaces other than said at least one of the plurality of intersecting surfaces to which the solar cell is provided, and
the intersecting surfaces to which the reflection plate is provided extending in respective directions that intersect each other.

2. The solar cell module as set forth in claim 1, wherein said at least one of the plurality of intersecting surfaces to which the solar cell is provided includes an intersecting surface whose portion intersecting the light receiving surface of the light collecting plate is the shortest in length of those of the plurality of intersecting surfaces.

3. The solar cell module as set forth in claim 1, wherein a portion, of the light collecting plate, in which adjacent ones of the plurality of intersecting surfaces intersect each other has a curved surface.

4. A solar photovoltaic device comprising a plurality of solar cell modules each of which is set forth in claim 1,
each of the light collecting plates being a trapezoid, and
the plurality of solar cell modules being arranged such that an upper base of one light collecting plate is adjacent to a lower base of another light collecting plate that is adjacent to the one light collecting plate.
